(19) United States
(12) Patent Application Publication
(10) Pub. No.: US 2010/0148348 A1
(43) Pub. Date: Jun. 17, 2010

(54) PACKAGE SUBSTRATE

(75) Inventors: Jae-Joon LEE, Suwon-si (KR); Jin-Yong An, Yongin-si (KR); Ki-Hwan Kim, Boryeong-si (KR); Seok-Kyu Lee, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/480,291

(22) Filed: Jun. 8, 2009

(30) Foreign Application Priority Data
Dec. 11, 2008 (KR) 10-2008-0125703

(51) Int. Cl. H01L 23/498

(52) U.S. Cl. 257/690; 257/E23.06

(57) ABSTRACT

A package substrate is disclosed. The package substrate as a printed circuit board, in which a semiconductor chip is mounted on one side thereof and the other side thereof is mounted on a main board, can include a substrate part, a first pad, which is formed on one side of the substrate part such that the first pad is electrically connected to the semiconductor chip, and a first solder resist layer, which is formed on one surface of the substrate part such that the first pad is exposed. Here, the first solder resist layer is divided into a pad portion and a dummy portion, the first pad is exposed in the pad portion, and the dummy portion is thinner than the pad portion. The package substrate can contribute to the formation of a structure in which thermal expansion coefficients are symmetrical between the top and bottom, thus preventing the warpage.

### CROSS-REFERENCE TO RELATED APPLICATIONS

This application claims the benefit of Korean Patent Application No. 10-2008-0125703, filed with the Korean Intellectual Property Office on Dec. 11, 2008, the disclosure of which is incorporated herein by reference in its entirety.

### BACKGROUND

1. Technical Field

The present invention relates to a package substrate.

2. Description of the Related Art

In step with the trends toward higher-performance, smaller-size electronic devices, the number of terminals on a semiconductor chip has been significantly increased, and thus the core of a flip Chip-Ball Grid Array (FC-BGA) substrate, which is used as a package substrate, is becoming increasingly thinner to improve the speed of signal transmittance. While the decreased thickness of the core, the loop inductance value also becomes smaller, significantly improving the speed of signal transmittance.

Coreless products, however, are vulnerable to warpage due to the lack of the core, which functions to withstand the warpage. The warpage of a substrate is resulted from the presence of several external forces, of which the most common form is heat.

In a thermally changeable environment, the warpage of the substrate may be caused by the difference in the coefficients of thermal expansion (CTE) between the top and bottom of the substrate from the neutral plane thereof. The design elements of the substrate may include the Cu portion of each layer, the plated volume, the volume of insulating material and the volume of SR, and a change in the design elements may be caused by a thermal mismatch between the top and bottom of the substrate. The greater the thermal mismatch, the greater the warpage of the substrate in the thermal environment becomes.

FIG. 1 is a plan view illustrating a package substrate 10 in accordance with the related art, and FIG. 2 is a bottom view illustrating the package substrate 10 in accordance with the related art. The package substrate 10 illustrated in FIGS. 1 and 2 is a coreless type.

As illustrated in FIG. 1, a semiconductor chip is mounted on an upper surface of the package substrate 10, and solder ball pad 2, on which solder balls are mounted for electrical connection to the semiconductor chip, is closely formed in the center portion of the package substrate 10. Then, as illustrated in FIG. 2, solder ball pad 4 is formed throughout a lower surface of the package substrate 10, for electrical connection to a main board.

Generally, the solder ball formed on the upper surface of the package substrate has a smaller diameter than that of the solder ball formed on the lower surface thereof, and thus the solder ball pad 2 formed on the upper surface of the package substrate is formed greater than the solder ball pad 4 formed on the lower surface of the package substrate. For example, a difference between the sums of the total area of the solder ball pads 2 and 4 may be as much as nine times.

FIG. 3 is a cross-sectional view illustrating the package substrate 10 in accordance with the related art. As illustrated in FIG. 3, the difference in area between the solder ball pads 2 and 4 on the upper and lower surfaces of the package substrate 10 may be related not only to the difference in open amount between solder resist layers 3 and 5 on the outermost layers but also to the difference in volume between circuit patterns inside the package substrate 10.

Moreover, the upper side of the package substrate 10 has a lower circuit pattern formation density than that of the lower side of the package substrate 10, and thus the ratio of the amount of copper is higher on the lower side of the package substrate 10, compared to the amount of polymer. The difference in density between the top and bottom sides of the substance making the package substrate 10 also causes the warpage.

### SUMMARY

The present invention provides a package substrate that can reduce warpage.

An aspect of the present invention provides a package substrate. The package substrate as a printed circuit board, in which a semiconductor chip is mounted on one side thereof and the other side thereof is mounted on a main board, includes a substrate part, a first pad, which is formed on one side of the substrate part such that the first pad is electrically connected to the semiconductor chip, and a first solder resist layer, which is formed on one surface of the substrate part such that the first pad is exposed. Here, the first solder resist layer is divided into a pad portion and a dummy portion, and the first pad is exposed in the pad portion. Here, the dummy portion is thinner than the pad portion.

The package substrate can include a second pad, which is formed on the other surface of the substrate part such that the second pad and the main board are electrically connected to each other, and a second solder resist layer, which is formed on the other surface of the substrate part such that the second pad is exposed. Here, the pad portion of the first solder resist layer and the second solder resist layer have the same thickness.

The dummy portion can be formed along outer edges of the pad portion, and the sum of the area of the first pad can be smaller than the sum of the area of the second pad.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a plan view illustrating a package substrate in accordance with the related art.

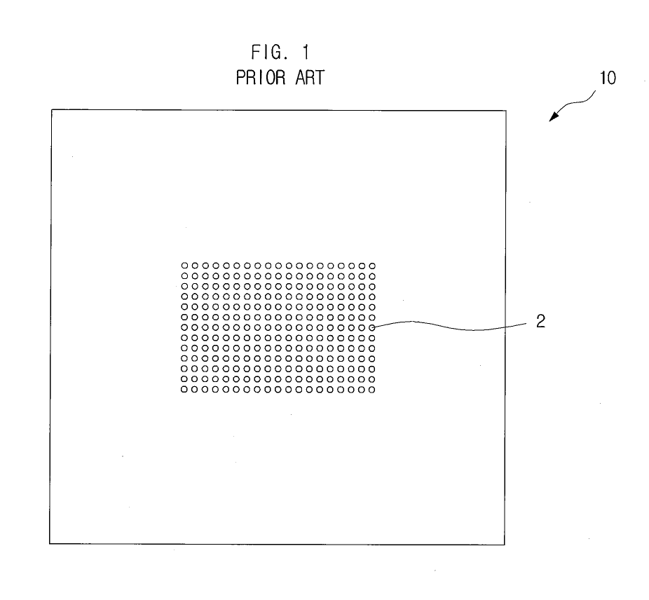

FIG. 2 is a bottom view illustrating a package substrate in accordance with the related art.

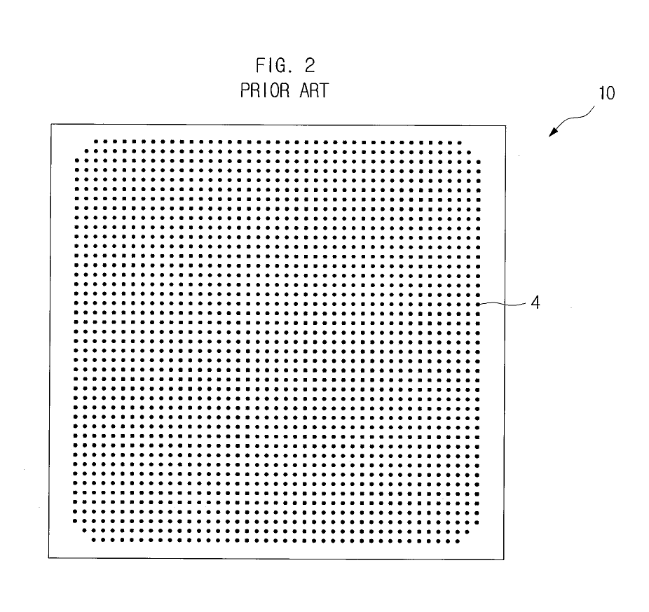

FIG. 3 is a cross-sectional view illustrating a package substrate in accordance with the related art.

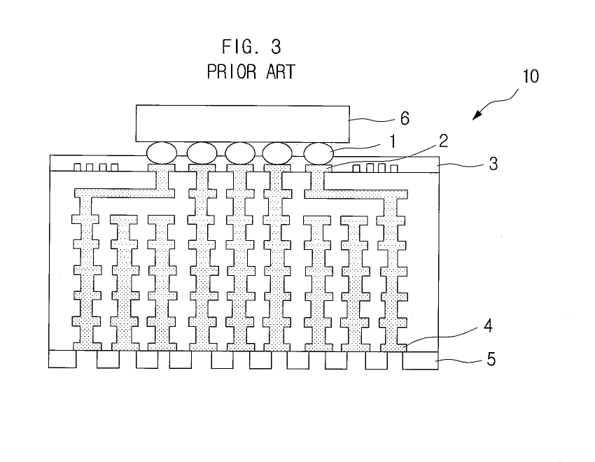

FIG. 4 is a cross-sectional view illustrating a package substrate in accordance with an embodiment of the present invention.

FIG. 5 is a perspective view illustrating a portion of a package substrate in accordance with another embodiment of the present invention.

FIG. 6 is an enlarged transverse section A-A′ of FIG. 5.

FIG. 7 is an enlarged transverse section B-B′ of FIG. 5.

### DETAILED DESCRIPTION

The features and advantages of this invention will become apparent through the below drawings and description.

A package substrate according to a certain embodiment of the present invention will be described below in more detail with reference to the accompanying drawings. Those components that are the same or are in correspondence are rendered the same reference numeral regardless of the figure number, and redundant descriptions are omitted.

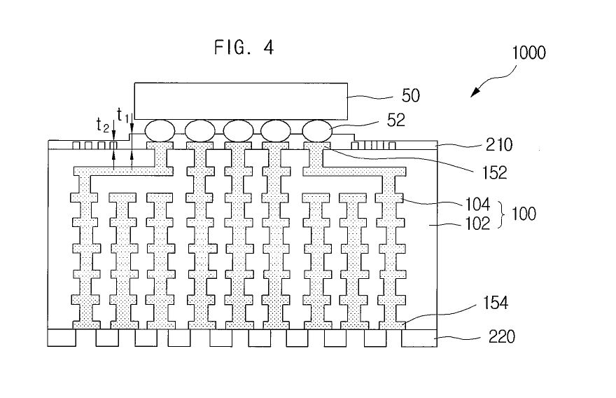

FIG. 4 is a cross-sectional view illustrating a package substrate in accordance with an embodiment of the present invention. As illustrated in FIG. 4, a package substrate 1000, which is a printed circuit board, in which a semiconductor chip 50 is mounted on one side thereof and of which the other side is mounted on a main board, in accordance with an embodiment of the present invention includes: a substrate part 100; a first pad 152, which is formed on one side of the substrate part 100 such that the first pad 152 is electrically connected to the semiconductor chip 50; and a first solder resist layer 210, which is formed on one surface of the substrate part 100 such that the first pad 152 is exposed and which is divided into a pad portion 212, in which the first pad is exposed, and a dummy portion 214, which is thinner than the pad portion 212. The package substrate 1000 in accordance with an embodiment of the present invention can contribute to the formation of a structure in which thermal expansion coefficients are symmetrical between the top and bottom, thus preventing the warpage.

The semiconductor chip 50 is mounted on one surface of the package substrate 1000, which itself is mounted on the main board, allowing the semiconductor chip 50 and the main board to be electrically connected to each other. Here, the main board is a substrate, on which the semiconductor chip 50 is to be mounted through the package substrate 1000, and can be a main substrate, for example, a mother board used in a computer.

The substrate part 100 can include an insulating layer 102 and a circuit pattern 104, which electrically connects the first pad 152 to a second pad 154, inside the insulating layer 102.

To shorten the signal transmitting path and implement a thinner shape, the substrate part 100 can be implemented in a coreless form, from which a coreless substrate constituted by reinforced glass is omitted, and can be formed by stacking a plurality of insulating layers 102, on which the circuit pattern 104 is formed.

The second pad 154 can be formed on the other surface of the substrate part 100 such that the second pad 154 and the main board are electrically connected to each other. The substrate part 100 and the main board are physically and electrically coupled to each other through a solder ball, and the second pad 154 can take the structure of a solder pad such that the solder ball can be mounted on the second pad 154. The second pad 154 can be evenly distributed and formed throughout the other surface of the substrate part 100.

A second solder resist layer 220 can be formed on the other surface of the substrate part 100. The second solder resist layer 220 covers and protects the circuit pattern 104 formed on the other surface of the substrate part 100, and a portion of the second solder resist layer 220 can be formed open in such a way that the second pad 154 is exposed.

The first pad 152 can be formed on one side of the substrate part 1000 such that the first pad 152 and the semiconductor chip 50 are electrically connected to each other. The package substrate 1000 and the semiconductor chip 50 can form a physical and electrical connection between them by using a solder ball 52, and the first pad 152 can take the structure of a solder pad such that the solder ball 52 can be mounted on the first pad 152.

The first solder resist layer 210 can be formed on one surface of the substrate part 100. The first solder resist layer 210 covers a portion of one surface of the substrate part 100 such that the first pad 152 can be exposed and the circuit pattern 104 formed on one surface of the substrate part 100 can be protected.

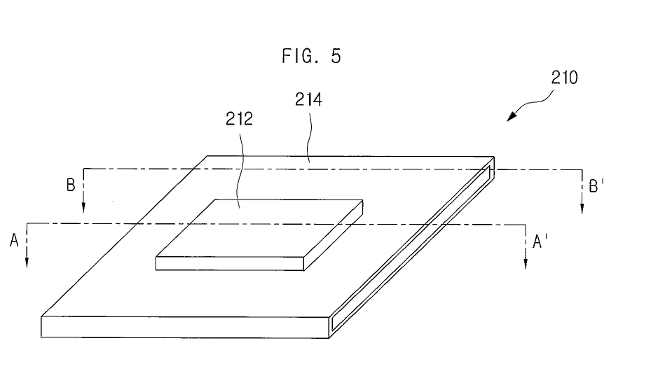

FIG. 5 is a perspective view illustrating a portion of the package substrate 1000 in accordance with an embodiment of the present invention. As illustrated in FIG. 5, the first solder resist layer 210 can be divided into the pad portion 212 and the dummy portion 214. The pad portion 212 is a portion that is opened such that the first pad 152 can be exposed, and the dummy portion 214 is a portion that surrounds the edges of the pad portion 212 and covers the circuit pattern 104 formed on one surface of the substrate part 100.

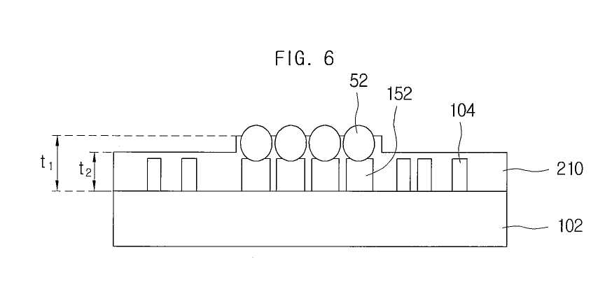

FIG. 6 is an enlarged transverse section A-A′ of FIG. 5. As illustrated in FIG. 6, the first solder resist layer 210 of the pad portion 212 can have a thickness “t1” to support the lateral side of the solder ball 52, in case the solder ball 52 is mounted on the first pad 152.

However, since the first solder resist layer 210 of the dummy portion 214 functions to cover and protect the circuit pattern 104 formed on one surface of the substrate part 100, the first solder resist layer 210 of the dummy portion 214 can have a thickness “t2” that is thinner than the thickness “t1” of the first solder resist layer 210 of the pad portion 212.

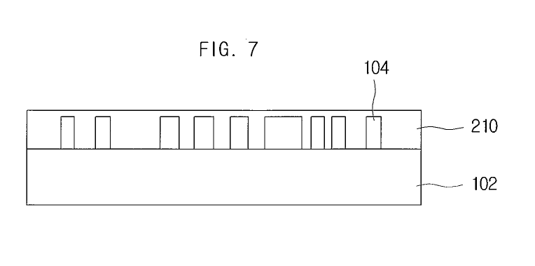

FIG. 7 is an enlarged transverse section B-B′ of FIG. 5. As illustrated in FIG. 7, the first solder resist layer 210 of the dummy portion 214 can fulfill its functions by covering one surface of the substrate part 100 such that the circuit pattern 104 formed on one surface of the substrate part 100 is not exposed.

Therefore, in the overall structure of the package substrate 1000 described above, the first pads 152 can be formed closely to one another in a center of the substrate part 100, taking the size of the semiconductor chip 50 into consideration. The solder ball 52 being coupled to the semiconductor chip 50 can be smaller than the solder ball being coupled to the main board, and thus the area of a single first pad 152 can be smaller than the area of a single second pad 154.

While the first pad 152 is concentrated in the center of one surface of the substrate part 100, the second pad 154 is formed throughout the other surface of the substrate part 100. As a result, the total area occupied by the first pad 152 can be smaller than that of the second pad 154.

Additionally, the circuit pattern 104, the first pad 152 and the second pad 154 can be made of a material including copper, and the insulating layer 102, the first solder resist layer 210 and the second solder resist layer 220 can be made of a material including polymer. Thus, there can be a smaller portion of copper in polymer on one surface of the substrate part 100 than on the other surface of the substrate part 100.

The overall structure of the package substrate 1000 can be simplified to a combination of copper and polymer, and the thermal expansion coefficients at the top and bottom of the structural body can be different, causing the warpage.

By forming the dummy portion 214 thinner than the pad portion 212, the amount of polymer in one surface of the package substrate 1000 can be reduced, and thus the difference between the ratios of copper in polymer at the top and bottom of the package substrate 1000 can be reduced. Therefore, by reducing the difference in thermal expansion coefficients at the top and bottom of the package substrate 1000, the warpage of the package substrate 1000 can be prevented.

Meanwhile, the first solder resist layer 210 and the second solder resist layer 220 can be simultaneously stacked and formed on either surface of the substrate part 100. After that, the dummy portion 214 of the first solder resist layer 210 can be formed by removing portions of the first solder resist layer 210, excluding the pad portion 212 of the first solder resist layer 210, through an additional process such as laser processing or grinding.

Here, the thickness of the pad portion 212 of the first solder resist layer 210 that is not given any additional process can be the same as that of the second solder resist layer 220.

As described above, the package substrate 1000 in accordance with an embodiment of the present invention can prevent the warpage by reducing a deviation in thermal expansion coefficients between the top and bottom of the package substrate 1000, by removing portions of the first solder resist layer 210 on the dummy portion 214, without changing the circuit pattern 104 of the substrate part 100, or the structure of the first pad 152 or the second pad 154.

While the spirit of the invention has been described in detail with reference to a particular embodiment, the embodiment is for illustrative purposes only and shall not limit the invention. It is to be appreciated that those skilled in the art can change or modify the embodiment without departing from the scope and spirit of the invention. As such, many embodiments other than that set forth above can be found in the appended claims.

What is claimed is:

1. A package substrate as a printed circuit board, a semiconductor chip being mounted on one side thereof and the other side thereof being mounted on a main board, the package substrate comprising:
a substrate part;
a first pad formed on one side of the substrate part such that the first pad is electrically connected to the semiconductor chip; and
a first solder resist layer formed on one surface of the substrate part such that the first pad is exposed, the first solder resist layer being divided into a pad portion and a dummy portion, the first pad being exposed in the pad portion,
wherein the dummy portion is thinner than the pad portion.

2. The package substrate of claim 1, further comprising:
a second pad formed on the other surface of the substrate part such that the second pad and the main board are electrically connected to each other; and
a second solder resist layer formed on the other surface of the substrate part such that the second pad is exposed.

3. The package substrate of claim 2, wherein the pad portion of the first solder resist layer and the second solder resist layer have a same thickness.

4. The package substrate of claim 1, wherein the dummy portion is formed along outer edges of the pad portion.

5. The package substrate of claim 2, wherein the sum of the area of the first pad is smaller than the sum of the area of the second pad.
